(19) United States
(12) Patent Application Publication
(10) Pub. No.: US 2022/0155966 A1
(43) Pub. Date: May 19, 2022

(54) Hybrid Cluster System and Computing Node Thereof

(71) Applicants: Inventec (Pudong) Technology Corp., Shanghai (CN); Inventec Corporation, Taipei (TW)

(72) Inventors: Hsueh-Chih Lu, Taipei (TW); Chih-Jen Chin, Taipei (TW); Lien-Feng Chen, Taipei (TW); Min-Hui Lin, Taipei (TW)

(21) Appl. No.: 17/121,609

(22) Filed: Dec. 14, 2020

(30) Foreign Application Priority Data
Nov. 19, 2020 (CN) 202011298416.8

(51) Int. Cl. G06F 3/06; H05K 7/14

(52) U.S. Cl. CPC G06F 3/067; H05K 7/1489; G06F 3/0604; G06F 3/0688

(57) ABSTRACT

A hybrid cluster system includes at least one computing node for providing computing resources and at least one storage node for providing storage resources. A specification of the at least one computing node is identical to a specification of the at least one storage node.

### BACKGROUND OF THE INVENTION

### 1. Field of the Invention

The present invention relates to a hybrid cluster system and computing node thereof, and more particularly, to a hybrid cluster system and computing node thereof capable of facilitating system update and enhancing product versatility and flexibility.

### 2. Description of the Prior Art

Most of conventional servers have special specifications and are not compatible with system interfaces of other servers, and there is no uniform size. Therefore, it can only rely on original design manufacturers to update or upgrade system, which obstructs update or upgrade. Besides, the conventional servers are usually only utilized for computing nodes, and may not support integration with storage devices. If there is a need for storage, it needs to configure an additional storage server. Therefore, how to save design cost and to integrate storage and computing requirements has become an important issue.

### SUMMARY OF THE INVENTION

It is therefore an objective of the present invention to provide a hybrid cluster system and computing node thereof capable of facilitating system update and enhancing product versatility and flexibility.

The present invention discloses a hybrid cluster system. The hybrid cluster system includes at least one computing node for providing computing resources and at least one storage node for providing storage resources. A specification of the at least one computing node is identical to a specification of the at least one storage node.

The present invention further discloses a computing node, for providing computing resources. The computing node includes a plurality of computing elements, wherein the computing node is coupled to a storage node, and a specification of the computing node is identical to a specification of the storage node.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a hybrid cluster system according to an embodiment of the present invention.

FIG. 2A is a schematic diagram of a hybrid cluster system according to an embodiment of the present invention.

FIG. 2B illustrates the hybrid cluster system shown in FIG. 2A according to an embodiment of the present invention.

FIG. 3 is a schematic diagram of a computing node according to an embodiment of the present invention.

FIG. 4 illustrates a schematic diagram of element configuration of the computing node shown in FIG. 3 according to an embodiment of the present invention.

FIG. 5 is a schematic diagram of a switch according to an embodiment of the present invention.

FIG. 6 is a schematic diagram of a backplane board according to an embodiment of the present invention.

FIG. 7 is a schematic diagram of a hybrid cluster system, an x86 platform server and users according to an embodiment of the present invention.

### DETAILED DESCRIPTION

The term “comprising” as used throughout the specification and subsequent claims is an open-ended fashion and should be interpreted as “including but not limited to”. The descriptions of “first” and “second” mentioned in the entire specification and subsequent claims are only used to distinguish different components and do not limit the order of generation.

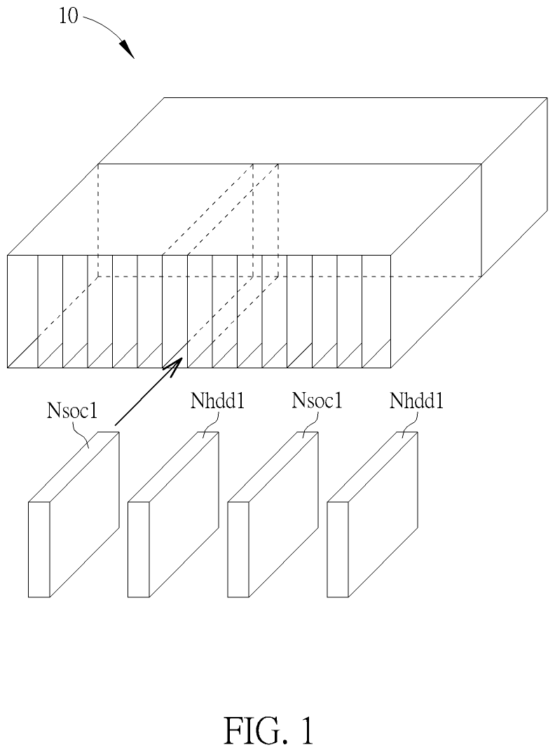

Please refer to FIG. 1, which is a schematic diagram of a hybrid cluster system 10 according to an embodiment of the present invention. The hybrid cluster system 10 may include computing nodes Nsoc1 and storage nodes Nhdd1. Accordingly, the hybrid cluster system 10 may provide computing and storage resources, to integrate storage and computing requirements. The computing nodes Nsoc1 virtualize virtual platforms of users. The computing nodes Nsoc1 may be advanced reduced instruction set computing machine (Advanced RISC Machine, ARM) micro servers, but are not limited to this. The storage nodes Nhdd1 are utilized for storing data, and the storage node Nhdd1 may be a 2.5-inch hard disk drive (2.5-inch HDD), but is not limited thereto. The size of the computing node Nsoc1 is the same with the size of the storage node Nhdd1; for example, both adopt the existing 2.5-inch standard specification. Moreover, the interface of the computing node Nsoc1 is the same with the interface of the storage node Nhdd1. In some embodiments, both of the computing node Nsoc1 and the storage node Nhdd1 adopt SFF-8639 connectors. In some embodiments, both of the computing node Nsoc1 and the storage node Nhdd1 adopt a non-volatile memory host controller interface specification or non-volatile memory express (NVMe) interface. In some embodiments, both of the computing node Nsoc1 and the storage node Nhdd1 adopt a peripheral component interconnect express (PCIe) interface. In some embodiments, the interface of the computing node Nsoc1 is identical to the interface of the storage node Nhdd1, and both support hot swapping/hot plugging.

In short, a specification of the computing node Nsoc1 is identical to a specification of the storage node Nhdd1. As a result, the computing node Nsoc1 may be compatible with the system interface set by the storage node Nhdd1, thereby saving design cost and enhancing product versatility. Moreover, the computing node Nsoc1 and the storage node Nhdd1 may replace each other; for example, the previously configured storage node Nhdd1 may be switched to be configured as a computing node Nsoc1, thereby facilitating system upgrade or update. Furthermore, a configured ratio of the number of the computing nodes Nsoc1 to the number of the storage nodes Nhdd1 may be adjusted according to different requirements, thereby increasing product flexibility.

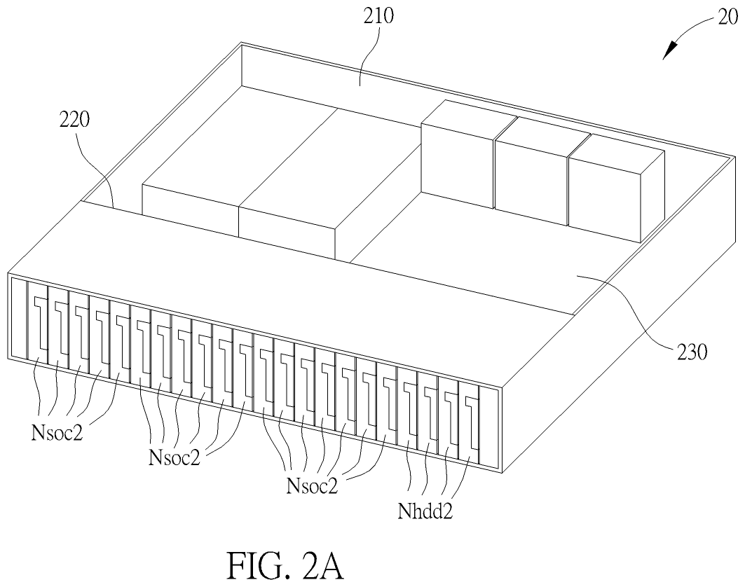

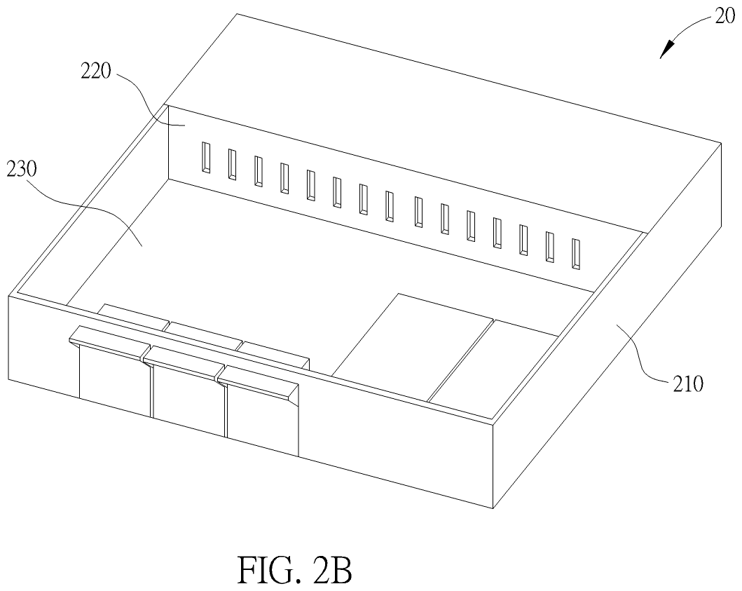

Specifically, please refer to FIG. 2A and FIG. 2B. FIG. 2A is a schematic diagram of a hybrid cluster system 20 according to an embodiment of the present invention, and FIG. 2B illustrates the hybrid cluster system 20 shown in FIG. 2A according to an embodiment of the present invention. The hybrid cluster system 20 may implements the hybrid cluster system 10. The hybrid cluster system 20 comprises a case 210, backplane boards 220, a switch 230, the computing node Nsoc2 and storage node Nhdd2. The case 210 houses the backplane boards 220, the switch 230, the computing nodes Nsoc2, and the storage nodes Nhdd2. The backplane boards 220 are electrically connected between the switch 230, the computing nodes Nsoc2 and the storage nodes Nhdd2, such that the computing nodes Nsoc2 may be coupled to the storage nodes Nhdd2. One backplane board 220 may include a plurality of bays arranged in an array, and the plurality of bays are separated by fixed distances in between. The computing nodes Nsoc2 or the storage nodes Nhdd2 are plugged into the bays of the backplane boards 220 to be electrically connected to the backplane boards 220. As a result, the backplane boards 220 may perform power transmission and signal transmission with the computing nodes Nsoc2 or the storage nodes Nhdd2. On the other hand, the switch 230 may perform addressing for the computing nodes Nsoc1 and the storage nodes Nhdd1 of the hybrid cluster system 20.

The computing nodes Nsoc2 and the storage nodes Nhdd2 may implement the computing nodes Nsoc1 and the storage nodes Nhdd1, respectively. In some embodiments, the storage node Nhdd2 may be a non-volatile memory, but is not limited thereto. In some embodiments, data may be stored in different storage nodes Nhdd2 in a distributed manner. The storage node Nhdd2 may be disposed in a chassis, and the size of the chassis is the size of the storage node Nhdd2. In some embodiments, the size of the computing node Nsoc2 may be less than or equal to the size of the storage node Nhdd2. In some embodiments, both of the computing node Nsoc2 and the storage node Nhdd2 conform to the 2.5-inch hard disk drive form factor, but are not limited to this. Both of the computing node Nsoc2 and the storage node Nhdd2 may also conform to 1.8-inch hard disk drive form factor or 3.5-inch hard disk drive form factor. In some embodiments, the interface of the computing node Nsoc2 and the interface of the storage node Nhdd2 are the same; for example, both adopt a non-volatile memory host controller interface specification or non-volatile memory express (NVMe) interface of the standard SFF-8639. Since sizes and interfaces of the computing nodes Nsoc 2 and the storage node nHDD 2 are the same, the computing node Nsoc 2 is compatible to the system interface set by the storage node nHDD 2 (for example, a system interface adopted by the existing technology). That is, the case 210 is commonly used (e.g. may be a case adopted by the existing technology), to save design cost and enhance product versatility.

Furthermore, since the computing nodes Nsoc 2 may be accommodated in bays of the storage nodes nHDD 2, a configured ratio of the number of the computing nodes Nsoc2 to the number of the storage nodes Nhdd2 may be adjusted according to different requirements. For example, in some embodiments, the hybrid cluster system 20 may include 3 backplane boards 220, and one backplane board 220 may include 8 bays, but is not limited thereto. That is, the hybrid cluster system 20 may include 24 bays, for the computing nodes Nsoc2 and the storage nodes Nhdd2 to be plugged into the backplane boards 220, and an upper limit of a total number of the computing nodes Nsoc2 and the storage nodes Nhdd2 is fixed (e.g. 24). As shown in FIG. 2, the hybrid cluster system 20 may include 20 computing nodes Nsoc2 and 4 storage nodes Nhdd2, but is not limited to this, e.g. the hybrid cluster system 20 may only include 18 computing nodes Nsoc2 and 5 storage nodes Nhdd2 wherein not all bays are plugged. In other words, a ratio of a number of the computing node Nsoc2 to a number of the storage node Nhdd2 is adjustable. the 24 bays of the hybrid cluster system 20 may be arranged to be separated by fixed distances in between. As a result, the computing nodes Nsoc2 or the storage nodes Nhdd2 plugged into the bays of the backplane boards 220 arranged to be align with four planes (i.e., a bottom plane and a top plane of the case 210, the backplane boards 220 and a frontplane board opposite to the backplane boards 220). As shown in FIG. 2, 20 computing nodes Nsoc2 are disposed in the left side of the hybrid cluster system 20 and 4 storage nodes Nhdd2 are disposed in the right side of the hybrid cluster system 20. That is, the computing nodes Nsoc2 and the storage nodes Nhdd2 may be arranged by classification. However, the present invention is not limited to this. As shown in FIG. 1, the computing nodes Nsoc1 and the storage nodes Nhdd1 may also be arranged alternatively.

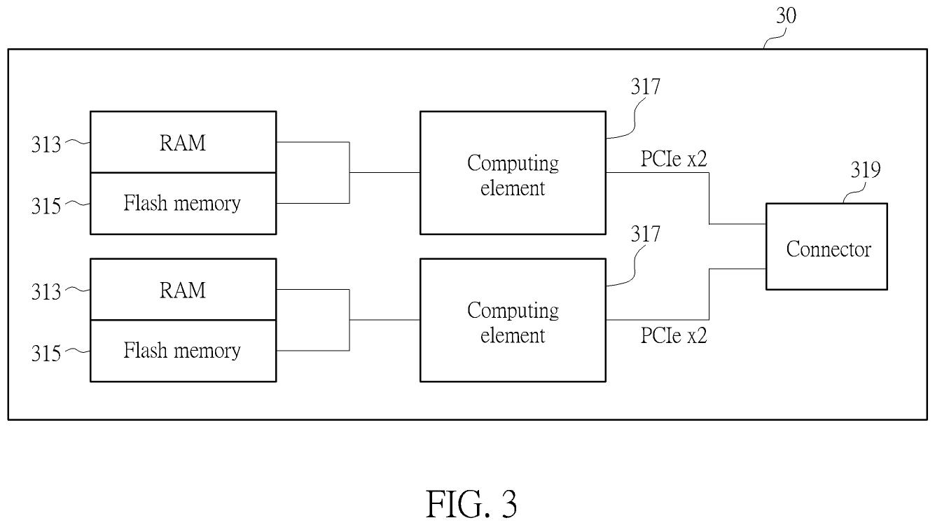

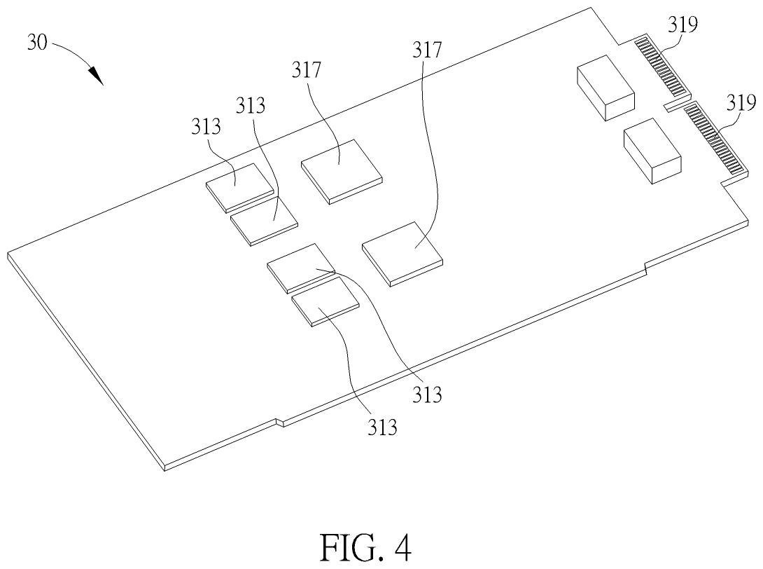

Please refer FIG. 3, which is a schematic diagram of a computing node Nsoc3 according to an embodiment of the present invention. The computing node Nsoc3 may implement the computing node Nsoc1. The computing node Nsoc3 may include random access memories (RAM) 313, flash memories 315, computing elements 317, and a connector 319. The computing element 317 is coupled between the random access memory 313, the flash memory 315 and the connector 319. In some embodiments, the data communication link between the random access memory 313, the flash memory 315, the computing device 317, and the connector 319 may comply with the peripheral component interconnect express (PCIe) standard. In some embodiments, the random access memory 313 may store an operating system, such as a Linux operating system. In some embodiments, the computing element 317 may be a system on a chip, and may process digital signals, analog signals, mixed signals or even signals with higher frequency, and may be applied in an embedded system. In some embodiments, the computing element 317 may be an ARM system on a chip. As shown in FIG. 3, the computing node Nsoc3 includes 2 computing elements 317, but is not limited to this, i.e. the computing nodes Nsoc3 may include two or more computing elements 317. The connector 319 supports the power transmission and signal transmission, and also supports thermal plug. In some embodiments, the connector 319 may adopt a PCIe interface. In some embodiments, the connector 319 may be an SFF-8639 connector. SFF-8639 may be referred to U.2 interface specified by SSD Form1 Factor Work Group. FIG. 4 illustrates a schematic diagram of element configuration of the computing node Nsoc3 shown in FIG. 3 according to an embodiment of the present invention. However, element configuration of the computing node Nsoc3 is not limited to the element configuration shown FIG. 4, and may be adjusted according to different design considerations.

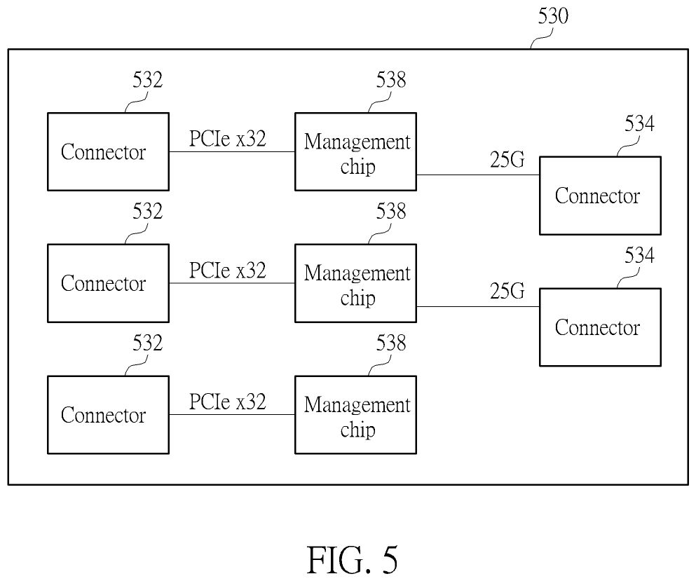

Please refer to FIG. 5, which is a schematic diagram of a switch 530 according to an embodiment of the present invention. The switch 530 may implement the switch 230. The switch 530 may be an Ethernet switch or other switches. The switch 530 may include connectors 532, 534 and management chips 538. The management chips 538 are coupled between the connectors 532 and 534. The data communication link between the connectors 532 and 534 and the management chips 538 may comply with the PCIe standard. The connector 532 may be a board to board (B2B) connector, but is not limited thereto. The connector 534 may be an SFP28 connector, but is not limited thereto. The connector 534 may be utilized as a network interface. The switch 530 may route data signals from the connector 534 to one of computing elements of computing nodes (e.g. the computing element 317 of the computing node Nsoc3 shown in FIG. 3). The management chip 538 may be a field programmable gate array (FPGA), but is not limited thereto, e.g. the management chip 538 may also be a programmable logic controller (PLC) or an application specific integrated circuit (ASIC). In some embodiments, the management chip 538 may manage the computing nodes and the storage nodes (e.g. the computing nodes Nsoc2 and the storage nodes Nhdd2 shown in FIG. 2). In some embodiments, the management chip 538 may manage computing elements of computing nodes (e.g. the computing elements 317 of computing node Nsoc3 shown in FIG. 3).

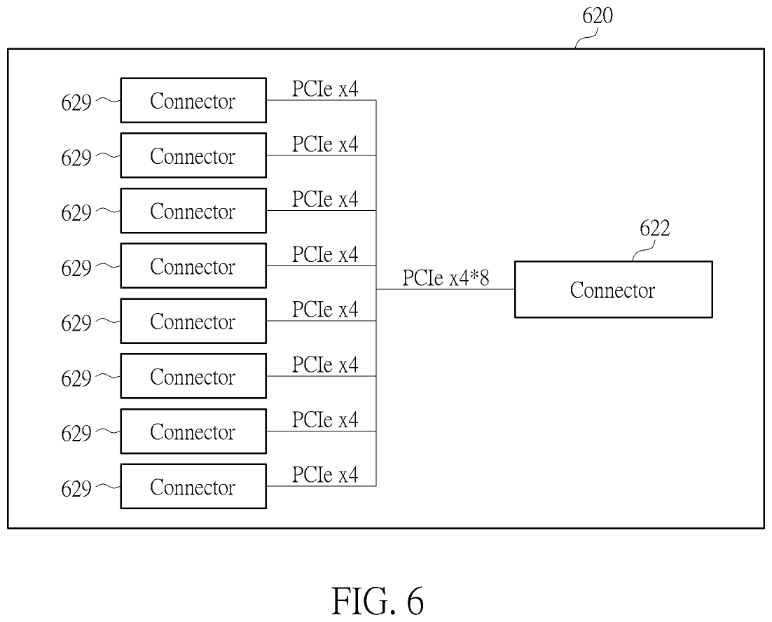

Please refer to FIG. 6, which is a schematic diagram of a backplane board 620 according to an embodiment of the present invention. The backplane board 620 may implement the backplane boards 220. The backplane 620 may include connectors 622 and 629. The data communication link between the connectors 622 and 629 may comply with the PCIe standard. The connector 622 may be a board-to-board connector, but is not limited to this. The connector 629 supports power transmission and signal transmission, and supports thermal plug. The connector 629 may be an SFF-8639 connector. The backplane board 620 relay and manage data, such that data is transmitted between a switch (e.g. the switch 230 shown in FIG. 2) and a corresponding computing node (e.g. the computing node Nsoc2 shown in FIG. 2). Since a hybrid cluster system (e.g. the hybrid cluster system 20 shown in FIG. 2) may not include a central processing unit (CPU) and is different from an existing manner of server management, the backplane board 620 may further include a microprocessor, to assist a management chip of a switch (e.g. the managing chip 538 of the switch 530 shown in FIG. 5) to manage the computing element of the computing node (e.g. the computing element 317 of the computing node Nsoc3 shown in FIG. 3).

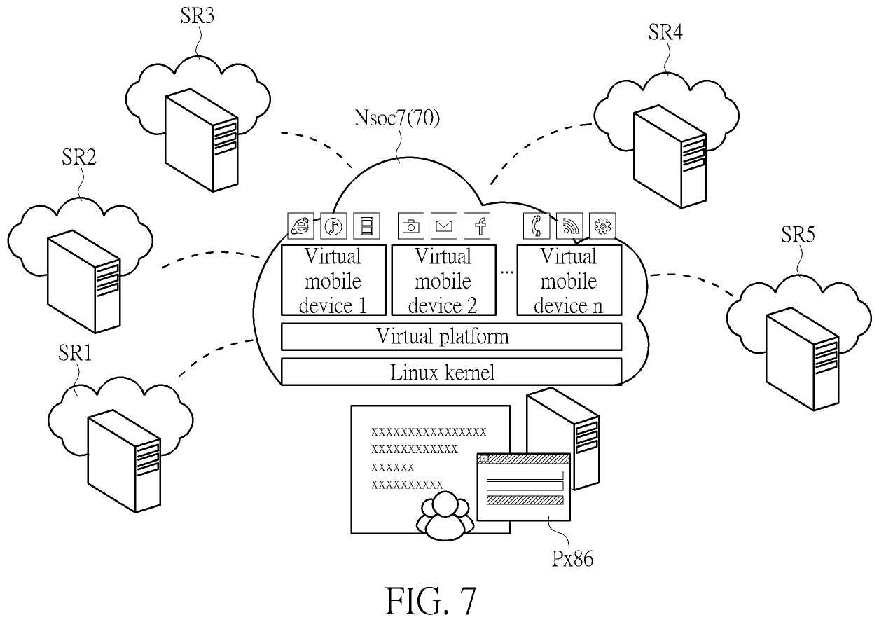

Please refer to FIG. 7, which is a schematic diagram of a hybrid cluster system 70, an x86 platform server Px86 and users SR1-SR5 according to an embodiment of the present invention. The hybrid cluster system 70 may implement the hybrid cluster system 10. In some embodiments, the hybrid cluster system 70 adopts Linux operating system kernel. The hybrid cluster system 70 may include a plurality of computing nodes Nsoc7, and the number of the computing nodes Nsoc7 of the hybrid cluster system 70 may be properly adjusted according to different models. For example, the hybrid cluster system 70 may contain 30 or more computing node Nsoc7. The computing node Nsoc7 in the hybrid cluster system 70 may be an ARM micro server. Compared with the x86 platform server Px86, the computing nodes Nsoc7 of the hybrid cluster system 70 has a high performance to price ratio; that is, cost and power consumption are lower in the same performance. The hybrid cluster system 70 connects ARM micro servers (i.e., the computing nodes Nsoc7) as an enormous computation center. As a result, the present invention may improve mobile application (APP) operating performance, thereby reducing cost and power consumption.

Specifically, the hybrid cluster system 70 virtualizes one computing node Nsoc7 as a plurality of mobile devices (such as mobile phones) through virtualization technology, which may provide cloud services for mobile application streaming platform. The users SR1 to SR5 do not need to download various applications, and may directly connect to the cloud to run all needed applications (such as mobile games, group marketing), to transfer computing loading to the data center for processing. In other words, all computing is completed in the data center, and images or sounds generated by the devices of the users SR1 to SR5 are processed in the data center before being streamed to the devices of the users SR1 to SR5. Since mobile devices are built in the hybrid cluster system 70 in a virtualized manner, the users SR1-SR5 only need to connect through the network and log in accounts to the x86 platform server Px86. Then, the users SR1-SR5 may remotely operate virtual mobile devices of the hybrid cluster system 70 with devices of the users SR1-SR5, to run all needed applications (such as mobile games, group marketing) without downloading and installing the needed application to the devices of the users SR1-SR5, such that operations are not limited to hardware specifications the devices of the users SR1-SR5. As a result, the users SR1-SR5 may reduce the risk of devices getting virus, and save device space and improve operating efficiency. Program developers may save maintenance costs (such as information security maintenance) to ensure that the application may run on various devices. Furthermore, in some embodiments, the computing nodes Nsoc7 of the hybrid cluster system 70 may be utilized to store resource files (e.g., codes, libraries, or environment configuration files) required by Android applications in operational container, and isolate the operational container from outside (e.g. Linux operating system) according to the sandbox mechanism, such that changes of contents of the operational container do not affect operations of outside (e.g. Linux operating system).

Since the hybrid cluster system 70 includes the computing nodes Nsoc7 and storage nodes (e.g. the storage nodes Nhdd2 shown in FIG. 2), the hybrid cluster system 70 may perform computing and storage and thus provide computing and storage resources. In some embodiments, a computing element (e.g. the computing element 317 shown in FIG. 3) may be mounted a virtual platform, and a computing element may simulate 2 to 3 virtual mobile devices, but is not limited thereto. In some embodiments, the computing element of the computing node Nsoc7 of the hybrid cluster system 70 (e.g. the computing element 317 shown in FIG. 3) provides image processing function and supports image compression. In some embodiments, when the user SR1 logs in account to the x86 internet server Px86, the x86 platform server Px86 assigns a virtual mobile device of the computing node Nsoc7 of the hybrid cluster system 70 to the user SR1, information related to the user SR1 (e.g., applications) may be stored in the storage node of the hybrid cluster system 70 (e.g. the storage node Nhdd2 shown in FIG. 2). After the computing node Nsoc7 completes related computing, images are encoded, compressed and transmitted to the device of the user SR1 via network. After the user SR1 receives the encoded and compressed images, the device of the user SR1 performs decoding to generate the images. As a result, the present invention may reduce image flow, so as to accelerate video transmission.

In summary, the computing nodes and the storage nodes of the hybrid cluster system have the same specification, such that the computing nodes may be compatible with the system interface set by the storage nodes, thereby saving design cost and enhancing product versatility. In addition, the computing nodes and the storage nodes may replace each other, thereby facilitating system upgrade or update. Furthermore, the configured ratio of the number of the computing nodes to the number of the storage nodes may be adjusted according to different requirements, thereby increasing product flexibility.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A hybrid cluster system, comprising:
at least one storage node, for providing storage resources; and
at least one computing node, for providing computing resources, wherein a specification of the at least one computing node is identical to a specification of the at least one storage node.

2. The hybrid cluster system of claim 1, wherein both of the at least one computing node and the at least one storage node conform to a 2.5-inch hard disk drive form factor.

3. The hybrid cluster system of claim 1, wherein both of the at least one computing node and the at least one storage node adopt a non-volatile memory host controller interface specification or non-volatile memory express (NVMe) interface.

4. The hybrid cluster system of claim 1, wherein both of a first connector of each of the at least one computing node and a second connector of each of the at least one storage node are SFF-8639 connectors.

5. The hybrid cluster system of claim 1, wherein an upper limit of a total number of the at least one computing node and the at least one storage node is fixed, and a ratio of a number of the at least one computing node to a number of the at least one storage node is adjustable.

6. The hybrid cluster system of claim 1, wherein the at least one computing node comprises a plurality of computing elements, and each of the plurality of computing elements is an advanced reduced instruction set computing machine (ARM) system on a chip, and each of the at least one computing node is an ARM micro server.

7. The hybrid cluster system of claim 1 further comprising:
a backplane board, comprising a plurality of bays, the plurality of bays are arranged in an array, wherein the plurality of bays are separated by fixed distances in between, at least one computing node and the at least one storage node are plugged into the plurality of bays of the backplane board to be electrically connected to the backplane board, and the backplane board performs power transmission and signal transmission with the at least one computing node.

8. The hybrid cluster system of claim 1 further comprising:
a switch, wherein the switch is an Ethernet switch, and the switch comprises a network interface, and the switch is utilized for routing signals from the network interface to one of the at least one computing node.

9. The hybrid cluster system of claim 1, wherein the at least one computing node and the at least one storage node are arranged to be align with four planes, and the at least one computing node and the at least one storage node are arranged alternatively or arranged by classification.

10. A computing node, for providing computing resources, comprising:
a plurality of computing elements, wherein the computing node is coupled to a storage node, and a specification of the computing node is identical to a specification of the storage node.
